(19) United States
(12) Patent Application Publication
(10) Pub. No.: US 2025/0254820 A1
(43) Pub. Date: Aug. 7, 2025

(54) ELECTRONIC DEVICE AND METHOD FOR PRODUCING ELECTRONIC DEVICE

(71) Applicant: NINTENDO CO., LTD., Kyoto-shi (JP)

(72) Inventors: Sai TAOKA, Kyoto-shi (JP); Hideaki KAMATA, Kyoto-shi (JP); Yasuhiro AMANO, Kyoto-shi (JP); Kohei ODANAKA, Kyoto-shi (JP)

(21) Appl. No.: 19/189,823

(22) Filed: Apr. 25, 2025

Related U.S. Application Data
(63) Continuation of application No. PCT/JP2022/042073, filed on Nov. 11, 2022.

(51) Int. Cl. H05K 7/20

(52) U.S. Cl. CPC H05K 7/20154; H05K 7/20145; H05K 7/20172; H05K 7/20418; H05K 7/2049

(57) ABSTRACT

The electronic device includes a housing, a fan accommodated in the housing, a heat generating component accommodated in the housing, and a heat transfer member which is in thermal contact with the heat generating component. The housing has an exhaust port, and a convex part protruding toward an interior space of the housing. The convex part presses the heat transfer member against the heat generating component and forms an exhaust path guiding air blown from the fan toward the exhaust port. The heat transfer member is arranged in the exhaust path.

### CROSS-REFERENCE TO RELATED APPLICATION

This application is a continuation application of International Patent Application No. PCT/JP2022/042073 filed on Nov. 11, 2022, the entire contents of which are incorporated herein by reference.

### TECHNICAL FIELD

The present disclosure relates to an electronic device and a method for producing an electronic device.

### BACKGROUND ART

Conventionally, in an electronic device, cooling a heat generating component by blowing cooling air from a fan onto a heat dissipation component attached to the heat generating component is known.

### SUMMARY

The summary of the present disclosure is as follows.

(1) An electronic device, comprising: a housing; a fan accommodated in the housing; a heat generating component accommodated in the housing; and a heat transfer member which is in thermal contact with the heat generating component, wherein the housing has an exhaust port, and a convex part protruding toward an interior space of the housing, and the convex part presses the heat transfer member against the heat generating component and forms an exhaust path guiding air blown from the fan toward the exhaust port, and the heat transfer member is arranged in the exhaust path.

(2) The electronic device described in above (1), further comprising a substrate accommodated in the housing, wherein the heat generating component is implemented on the substrate.

(3) The electronic device described in above (2), wherein the heat transfer member is electrically connected to a ground electrode of the substrate.

(4) The electronic device described in above (2) or (3), wherein the heat generating component includes a first heat generating component, and a second heat generating component having a heat generation amount which is less than the first heat generating component, and in a plane view of the substrate, the first heat generating component is arranged in a position overlapping the exhaust path, and the second heat generating component is not arranged in a position overlapping the exhaust path.

(5) The electronic device described in any one of above (2) to (4), further comprising a shielding member covering the heat generating component and the heat transfer member, wherein the convex part presses the heat transfer member against the heat generating component via the shielding member.

(6) The electronic device described in above (5), wherein the shielding member has an opening, and the heat transfer member has a heat dissipation fin exposed from the opening and arranged in the exhaust path.

(7) The electronic device described in above (5) or (6), wherein the shielding member is electrically connected to a ground electrode of the substrate, and the convex part presses the shielding member against the heat transfer member, and the heat transfer member is electrically connected to the ground electrode via the shielding member.

(8) The electronic device described in any one of above (5) to (7), wherein the shielding member has an engagement part elastically deforming to engage with a side surface of the substrate, and the engagement part is electrically connected to a ground electrode of the substrate, and the convex part presses the shielding member against the substrate so as to maintain an engagement state between the engagement part and the side surface of the substrate.

(9) The electronic device described in above (8), wherein the engagement part has a protrusion holding the substrate in a thickness direction of the substrate.

(10) The electronic device described in above (8) or (9), wherein the engagement part has a tapered tip extending outside the substrate.

(11) A method for producing an electronic device, comprising: forming a housing by assembling a first housing and a second housing such that a heat generating component and a heat transfer member which is in thermal contact with the heat generating component are accommodated in the housing, wherein the first housing or the second housing has a convex part protruding toward an interior space of the housing, and the convex part presses the heat transfer member against the heat generating component when the first housing and the second housing are assembled.

### BRIEF DESCRIPTION OF DRAWINGS

Embodiments of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a front perspective view of an electronic device according to an embodiment of the present disclosure.

FIG. 2 is a bottom view of the electronic device according to the embodiment of the present disclosure.

FIG. 3 is a top view of the electronic device according to the embodiment of the present disclosure.

FIG. 4 is a front view of a second housing showing an inner surface of the second housing.

FIG. 5 is a rear view of the electronic device showing components accommodated in the housing.

FIG. 6 is a rear view of the electronic device showing electronic components implemented on a substrate.

FIG. 7 is a perspective view of a heat transfer member.

FIG. 8 is a perspective view of a shielding member.

FIG. 9 is a partial cross-sectional perspective view of the electronic device showing an engagement state between the shielding member and the substrate.

FIG. 10 is a partial cross-sectional view of the electronic device taken along line A-A of FIG. 5.

### DETAILED DESCRIPTION

The embodiments of the present disclosure will be described in detail below with reference to the attached drawings. Note that in the following description, identical constituent elements have been assigned the same reference sign.

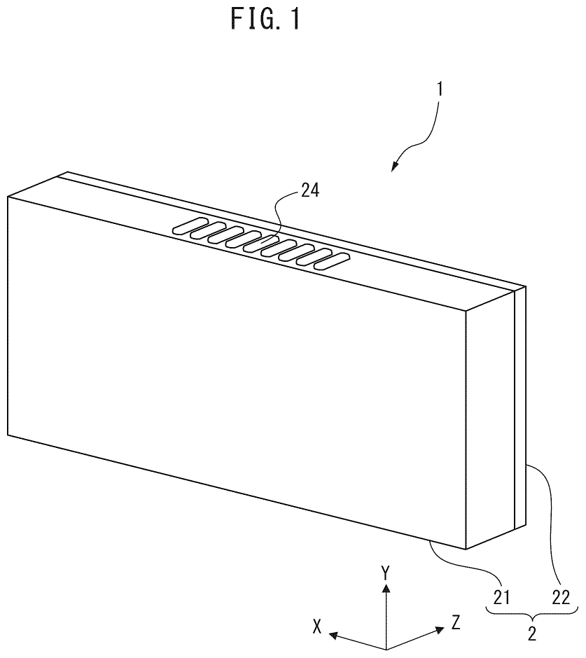

FIG. 1 is a front perspective view of an electronic device 1 according to an embodiment of the present disclosure. In the present embodiment, the electronic device 1 is a portable electronic device, such as a portable game machine, a tablet terminal, a smartphone, or an e-book reader. In the present description, the configuration of the electronic device 1 is described using an X Y Z orthogonal coordinate system set relative to the electronic device 1. When the electronic device 1, held by a user, faces the user, the X-axis direction corresponds to the left-right direction of the electronic device 1, the Y-axis direction corresponds to the upward-downward direction of the electronic device 1, and the Z-axis direction corresponds to the depth direction (thickness direction) of the electronic device 1. The left and right side surfaces of the electronic device 1 are spaced apart in the X-axis direction, the upper and lower surfaces of the electronic device 1 are spaced apart in the Y-axis direction, and the front and back surfaces of the electronic device 1 are spaced apart in the Z-axis direction.

As shown in FIG. 1, the electronic device 1 includes a housing 2. The housing 2 has a rectangular parallelepiped shape and forms the outer surface of the electronic device 1. The housing 2 is rectangular when viewed from the Z-axis direction, the X-axis direction corresponds to the longitudinal direction of the electronic device 1 and the housing 2, and the Y-axis direction corresponds to the lateral direction of the electronic device 1 and the housing 2.

In the present embodiment, the housing 2 includes a first housing 21 and a second housing 22, and is formed by assembling the first housing 21 and the second housing 22. The first housing 21 and the second housing 22 define the interior space of the housing 2 when the first housing 21 and the second housing 22 are assembled. For example, the first housing 21 and the second housing 22 are each composed of resin and are molded by injection molding or the like.

As shown in FIG. 1, in the Z-axis direction, the first housing 21 is arranged on the front side of the electronic device 1, and the second housing 22 is arranged on the rear side of the electronic device 1. The front side of the electronic device 1 faces the user when the electronic device 1 is used by the user. For example, a display (not illustrated) for displaying visual information (characters, images, etc.) to the user is provided on the front side of the electronic device 1.

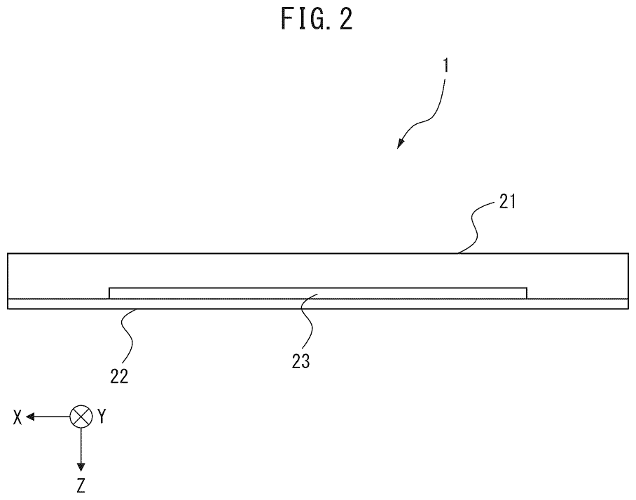

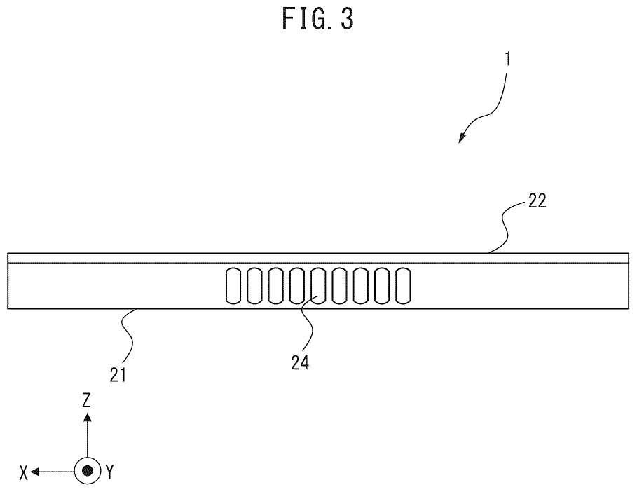

FIG. 2 is a bottom view of the electronic device 1 according to the embodiment of the present disclosure, and FIG. 3 is a top view of the electronic device 1 according to the embodiment of the present disclosure. The housing 2 has an intake port 23 and an exhaust port 24. The intake 10 port 23 and the exhaust port 24 are arranged in positions facing each other on the side surface of the housing 2. In the present embodiment, the intake port 23 is formed on the lower surface (bottom surface) of the housing 2, and the exhaust port 24 is formed on the upper surface of the housing 2. In the present embodiment, the intake port 23 and the exhaust port 24 are each formed in the first housing 21, and are arranged in the central region of the electronic device 1 in the X-axis direction.

As shown in FIG. 2, the intake port 23 is formed as a single slit-shaped hole extending in the X-axis direction. On the other hand, as shown in FIG. 3, the exhaust port 24 is formed as a plurality of holes arranged at equal intervals in the X-axis direction. The intake port 23 and the exhaust port 24 each communicate the interior space of the housing 2 with the outside of the housing 2. Note that the shapes of the intake port 23 and the exhaust port 24 are merely examples, and the intake port 23 and the exhaust port 24 may have other shapes. Furthermore, the intake port 23 and the exhaust port 24 may be formed in the second housing 22 or the first housing 21 and the second housing 22.

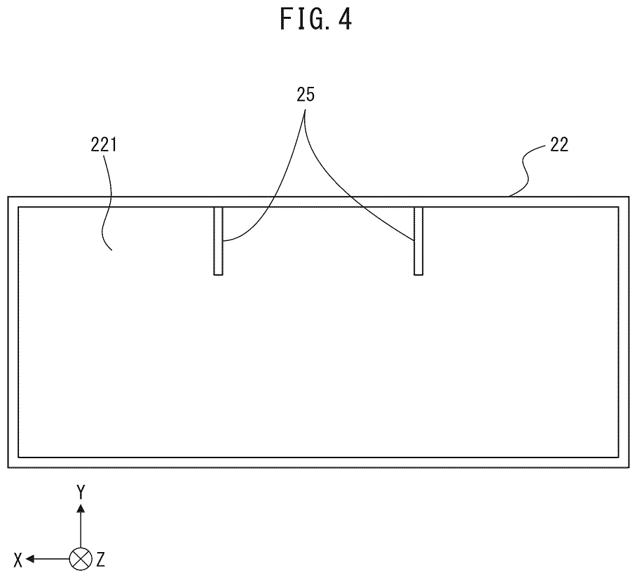

FIG. 4 is a front view of the second housing 22 showing an inner surface 221 of the second housing 22. As shown in FIG. 4, the second housing 22 has a pair of convex parts 25. Each of the pair of convex parts 25 protrudes in the Z-axis direction from the inner surface 221 of the second housing 22. Thus, when the second housing 22 is assembled with the first housing 21 to form the housing 2, the convex parts 25 protrude toward the interior space of the housing 2. Furthermore, the convex parts 25 are positioned outward of the exhaust port 24 in the X-axis direction, and extend in the Y-axis direction from the upper surface toward the lower surface of the second housing 22.

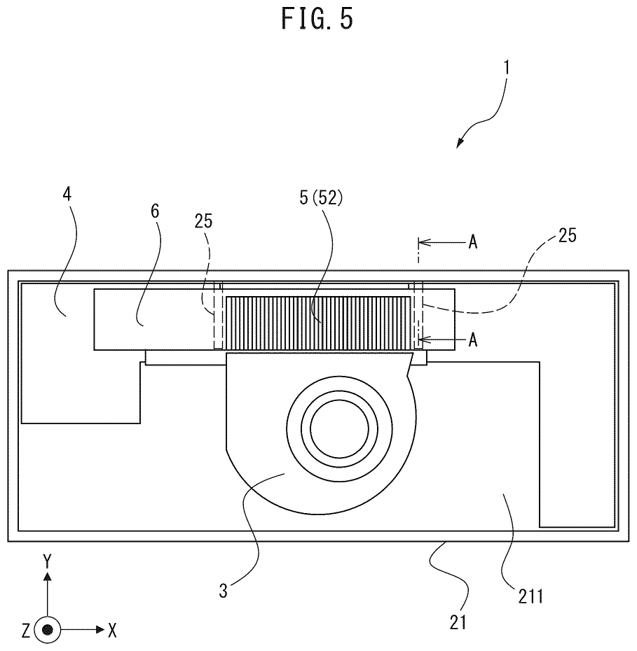

Internal components of the electronic device 1 are accommodated in the housing 2. FIG. 5 is a rear view of the electronic device 1 showing components accommodated in the housing 2. FIG. 5 shows the electronic device 1 in a state in which the second housing 22 is removed. In FIG. 5, the positions of the pair of convex parts 25 when the second housing 22 is assembled with the first housing 21 are represented by dashed lines. In the present embodiment, the components are attached to the inner surface 211 of the first housing 21, and the second housing 22 is assembled with the first housing 21 so as to cover the components attached to the inner surface 211 of the first housing 21. Thus, the components are accommodated inside the first housing 21 and the second housing 22, i.e., inside the housing 2, by assembling the first housing 21 and the second housing 22.

The electronic device 1 includes a fan 3, a substrate 4, electronic components on the substrate 4, a heat transfer member 5, and a shielding member 6 as internal components accommodated in the housing 2. The fan 3, the substrate 4, and the shielding member 6 are each attached to the housing 2 (first housing 21 in the present embodiment) by a fastening member such as a screw (not illustrated). The heat transfer member 5 is held on the substrate 4 by the shielding member 6.

The fan 3 is arranged in the interior space of the housing 2, and is arranged between the intake port 23 and the exhaust port 24 in the Y-axis direction. The fan 3 generates an air flow from the intake port 23 to the exhaust port 24. When the fan 3 is operated, air is drawn into the fan 3 from the outside of the housing 2 through the intake port 23, and the air is blown from the fan 3. The air blown from the fan 3 cools the heat transfer member 5 and is discharged to the outside of the housing 2 from the exhaust port 24. That is, the intake port 23 functions as an inlet for the air drawn into the fan 3, and the exhaust port 24 functions as an outlet for the air blown from the fan 3.

The substrate 4 is arranged in the interior space of the housing 2, and a part of the substrate 4 is arranged between the fan 3 and the exhaust port 24 in the Y-axis direction. The substrate 4 is, for example, a multi-layer substrate, and a plurality of electronic components are implemented on the substrate 4.

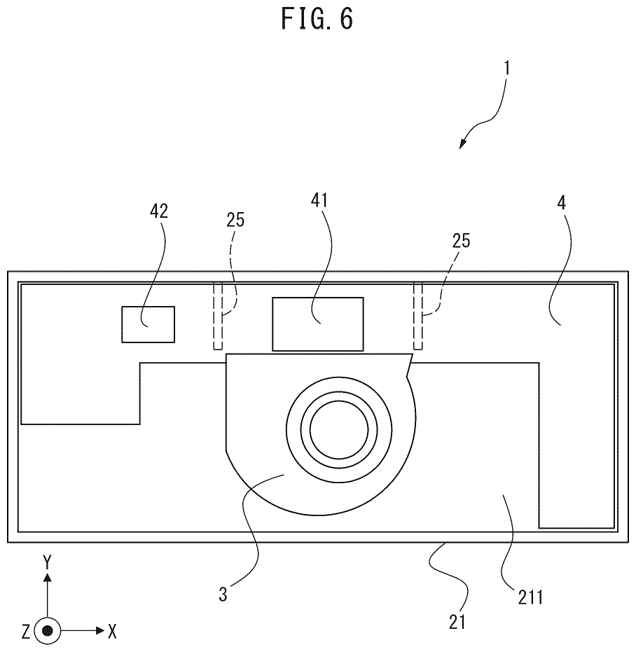

FIG. 6 is a rear view of the electronic device 1 showing the electronic components implemented on the substrate 4. FIG. 6 shows the electronic device 1 in a state in which the second housing 22, the shielding member 6, and the heat transfer member 5 are removed. The positions of a pair of convex parts 25 when the second housing 22 is assembled with the first housing 21 are represented by dashed lines in FIG. 6. As shown in FIG. 6, a system on a chip (SoC) 41 and a Wi-Fi module 42 are implemented on the surface of the substrate 4.

The SoC 41 has a CPU and executes various controls of the electronic device 1. The Wi-Fi™ module 42 has an antenna and enables Wi-Fi communication of the electronic device 1. The SoC 41 and the Wi-Fi module 42 are heat generating components which generate heat when powered. The heat generation amount of the SoC 41 is greater than that of the Wi-Fi module 42. The SoC 41 is an example of a first heat generating component, and the Wi-Fi module 42 is an example of a second heat generating component having a heat generation amount less than the first heat generating component. These heat generating components are accommodated in the housing 2 in a state implemented on the substrate 4.

As indicated by the dashed lines in FIGS. 5 and 6, the pair of convex parts 25 of the second housing 22 extend in the Y-axis direction from an end of the exhaust port 24 to an end of the fan 3 in a plane view (the XY plane shown in FIGS. 5 and 6) of the substrate 4. Thus, the pair of convex parts 25 form an exhaust path guiding the air blown from the fan 3 toward the exhaust port 24, and promote the flow of the blown air from the fan 3 to the exhaust port 24.

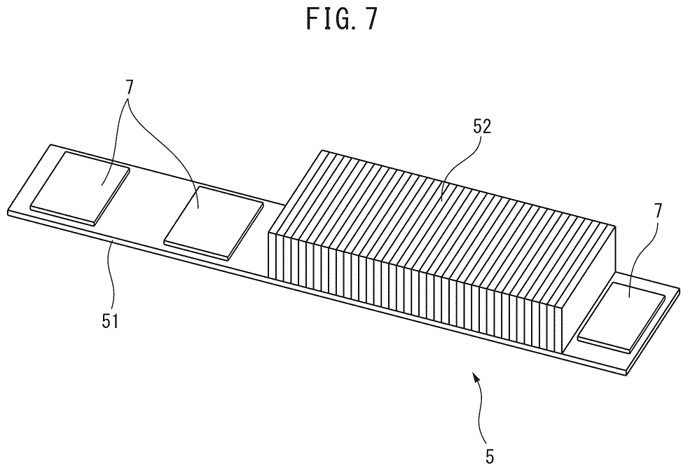

FIG. 7 is a perspective view of the heat transfer member 5. The heat transfer member 5 is arranged on the substrate 4 in the interior space of the housing 2, and covers the substrate 4. In the present embodiment, the heat transfer member 5 is arranged on the SoC 41 and the Wi-Fi module 42 on the substrate 4. The heat transfer member 5 is in thermal contact with the heat generating components on the substrate 4, such as the SoC 41 and the Wi-Fi module 42, and dissipates heat generated by the heat generating components. Thus, the heat generated by the heat generating components on the substrate 4 is primarily conducted to the heat transfer member 5, and the heat dissipation of the heat generating components is realized by cooling the heat transfer member 5. The heat transfer member 5 has electrical conductivity and is composed of, for example, a metal such as copper or aluminum, graphite, ceramics, etc.

In the present embodiment, the heat transfer member 5 includes a metal plate 51 and a heat dissipation fin 52. The metal plate 51 is arranged on the heat generating components implemented on the substrate 4, and the heat dissipation fin 52 is arranged on the metal plate 51.

The heat dissipation fin 52 is connected to the metal plate 51 by, for example, welding or bonding. Note that the heat dissipation fin 52 may be formed integrally with the metal plate 51. The heat generated by the heat generating component on the substrate 4 is conducted to the heat dissipation fin 52 via the metal plate 51.

Furthermore, gaskets 7 are provided on the metal plate 51. In the present embodiment, three gaskets 7 are attached to the metal plate 51 by an adhesive member (for example, adhesive or adhesive tape). The gaskets 7 are conductive and are composed of, for example, urethane foam, silicone rubber, etc.

The heat dissipation fin 52 has a plurality of fins and are configured so that air flows between the plurality of fins. As shown in FIG. 5, the heat dissipation fin 52 is arranged between the pair of convex parts 25 in the X-axis direction. That is, the heat dissipation fin 52 is arranged in the exhaust path formed by the pair of convex parts 25. The heat dissipation fin 52 faces the outlet of the fan 3 in the Y-axis direction, and the air blown from the fan 3 passes through the heat dissipation fin 52 and is discharged from the exhaust port 24. At this time, since the pair of convex parts 25 forming the exhaust path suppresses the air blown from the fan 3 from leaking outside the heat dissipation fin 52, the cooling effect of the heat dissipation fin 52 due to the blown air can be enhanced. The fin shape of the heat dissipation fin 52 may be a pin-shaped, bellows-shaped, etc.

Furthermore, as shown in FIG. 6, the SoC 41 is arranged between the pair of convex parts 25 in the X-axis direction and is arranged at a position overlapping the exhaust path in a plane view of the substrate 4. That is, the SoC 41 is arranged at a position overlapping the heat dissipation fin 52 in the plane view of the substrate 4 and is covered by the heat dissipation fin 52. On the other hand, the Wi-Fi module 42 is arranged outside the pair of convex parts 25 in the X-axis direction and is not arranged at a position overlapping the exhaust path in the plane view of the substrate 4. That is, the Wi-Fi module 42 is arranged at a position not overlapping the heat dissipation fin 52 in the plane view of the substrate 4 and is covered by the metal plate 51. In this case, the thermal conduction from the SoC 41 to the heat dissipation fin 52 is promoted as compared to the thermal conduction from the Wi-Fi module 42 to the heat dissipation fin 52. As a result, the cooling effect on the SoC 41, which has a large heat generation amount, is higher than the cooling effect on the Wi-Fi module 42, which has a small heat generation amount. Thus, even if the area of the substrate 4 on the exhaust path is limited, by dissipating heat from the plurality of heat generating components with different heat generation amounts in an appropriate priority order, the heat generation amount of the entire electronic device 1 can be suppressed.

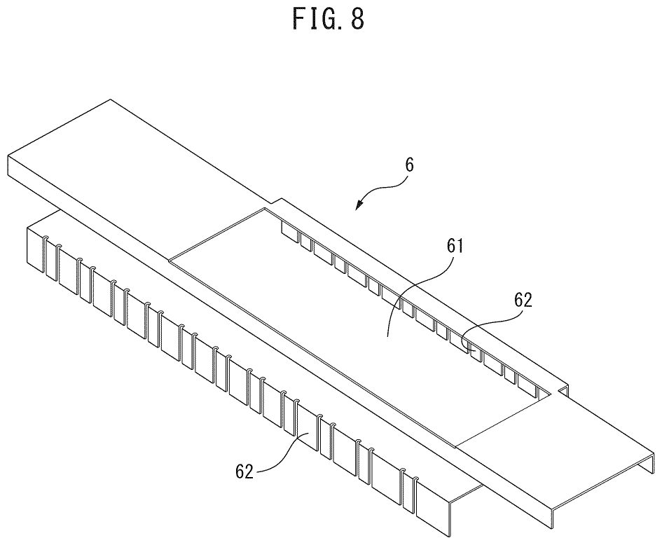

FIG. 8 is a perspective view of the shielding member 6. The shielding member 6 is arranged on the substrate 4 and the heat transfer member 5 in the interior space of the housing 2, and covers the substrate 4 and the heat transfer member 5. The shielding member 6 is attached to the substrate 4 and holds the heat transfer member 5 on the substrate 4.

In the present embodiment, as shown in FIG. 8, the shielding member 6 has an opening 61 and covers the heat transfer member 5 so that the heat dissipation fin 52 of the heat transfer member 5 is exposed from the opening 61. That is, the shielding member 6 covers a part of the heat transfer member 5, and the heat dissipation fin 52 protrudes from the opening 61 of the shielding member 6 into the space between the pair of convex parts 25. As a result, air blown from the fan 3 toward the heat dissipation fin 52 can be prevented from being blocked by the shielding member 6. Furthermore, by covering a part of the heat transfer member 5 with the shielding member 6, the dissipation of heat conducted from the heat generating components to the heat transfer member 5 can be suppressed, whereby the heat dissipation effect by the heat transfer member 5 can be further enhanced.

The shielding member 6 has electrical conductivity and is composed of, for example, aluminum, beryllium copper, permalloy, etc. As shown in FIG. 5, the heat transfer member 5 and the shielding member 6 cover the electronic components (the SoC 41 and the Wi-Fi module 42 in the present embodiment) on the substrate 4, and provide an electromagnetic shielding effect. That is, the heat transfer member 5 and the shielding member 6 block electromagnetic waves emitted by the electronic components on the substrate 4 and electromagnetic waves emitted from outside of the electronic device 1 toward the electronic components on the substrate 4.

Furthermore, as shown in FIG. 8, the shielding member 6 has engagement parts 62 engaging with the substrate 4. In the present embodiment, the engagement parts 62 are provided on both sides of the opening 61, and engage with the side surface of the substrate 4. A plurality of slits are formed in the engagement parts 62. Due to this shape, when a force is applied to the engagement parts 62, the engagement parts 62 elastically deform.

The pair of engagement parts 62 are spaced apart in the Y-axis direction so as to hold the substrate 4 in the Y-axis direction. The distance between the engagement part 62 provided on one side of the opening 61 and the engagement part 62 provided on the other side of the opening 61 is shorter than the length of the substrate 4 held by the shielding member 6. Thus, the engagement parts 62 come into contact with the side surface of the substrate 4 and elastically deform when the shielding member 6 is attached to the substrate 4. That is, the engagement parts 62 elastically deform to engage with the side surface of the substrate 4. As a result, the engagement parts 62 can reliably engage with the side surface of the substrate 4.

A ground electrode is provided on the side surface of the substrate 4 by an end face through hole or the like. Thus, when the engagement parts 62 engage with the side surface of the substrate 4, the engagement parts 62 are electrically connected to the ground electrode of the substrate 4. As a result, the potential of the shielding member 6 can be set to the ground potential, thereby improving the electromagnetic shielding effect of the shielding member 6.

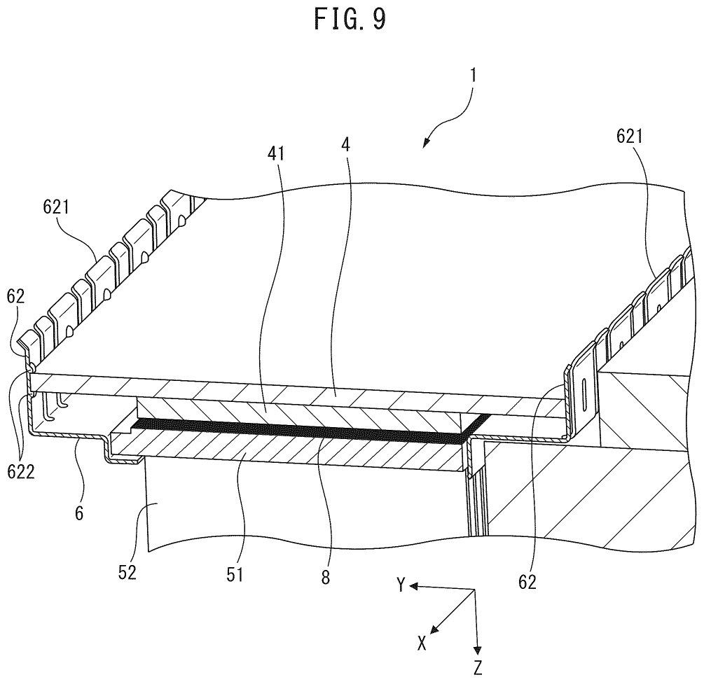

FIG. 9 is a partial cross-sectional perspective view of the electronic device 1 showing the engagement state between the shielding member 6 and the substrate 4. As shown in FIG. 9, the shielding member 6 holds both side surfaces of the substrate 4 and is attached to the substrate 4. In the present embodiment, the engagement part 62 has a tapered tip 621 extending outward from the substrate 4. When the shielding member 6 is attached to the substrate 4, the tip 621 of the engagement part 62 first comes into contact with the side surface of the substrate 4, and a force for promoting elastic deformation of the engagement part 62 outward is exerted on the engagement part 62. As a result, the engagement part 62 spreads outward from the substrate 4 and is inserted into the side surface of the substrate 4. Thus, by providing the engagement part 62 with the tapered tip 621, the attachment of the shielding member 6 to the substrate 4 can be facilitated.

The engagement part 62 also has protrusions 622 holding the substrate 4 in the thickness direction (Z-axis direction) of the substrate 4. The protrusion 622 provided on the tip side of the engagement part 62 engages with the back surface (upper surface in FIG. 9) of the substrate 4, and the protrusion 622 provided on the base end side of the engagement part 62 engages with the front surface (lower surface in FIG. 9) of the substrate 4. By holding the substrate 4 with the protrusions 622, the fixation of the shielding member 6 to the substrate 4 can be strengthened.

As shown in FIG. 9, the SoC 41 on the substrate 4 contacts the metal plate 51 of the heat transfer member 5 via thermal grease 8. Furthermore, though not illustrated, the Wi-Fi module 42 on the substrate 4 also contacts the metal plate 51 of the heat transfer member 5 via the thermal grease 8. The thermal grease 8 promotes thermal conduction from the heat generating components on the substrate 4 to the heat transfer member 5, and the heat transfer member 5 comes into thermal contact with the heat generating components on the substrate 4.

The heat generating components on the substrate 4 may be in direct contact with the heat transfer member 5. Also, the heat generating components may be arranged on the back surface of the substrate 4, and thermal vias for conducting the heat of the heat generating components to the front surface of the substrate 4 may be formed in the substrate 4. In this case, the heat transfer member 5 contacts the thermal vias on the substrate 4 directly or via thermal grease. In either case, the heat generated by the heat generating components is conducted to the heat transfer member 5, and the heat transfer member 5 is in thermal contact with the heat generating components.

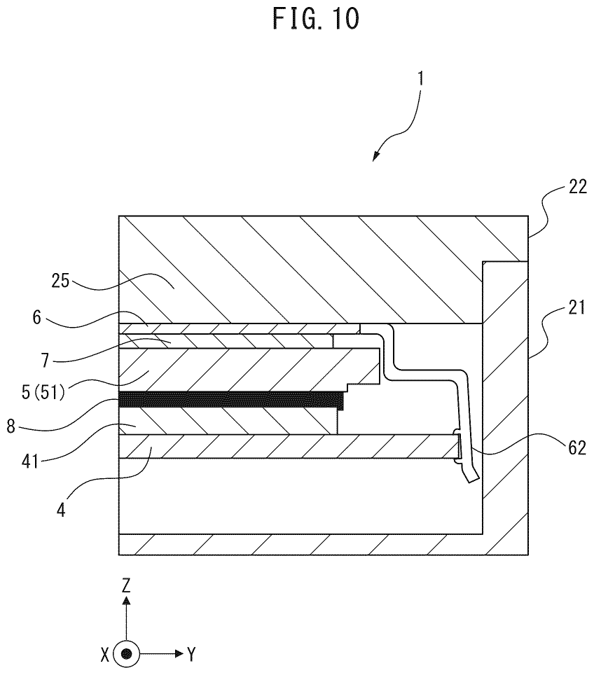

FIG. 10 is a partial cross-sectional view of the electronic device 1 taken along line A-A of FIG. 5. In the production process of the electronic device 1, the housing 2 is formed by assembling the first housing 21 and the second housing 22 such that the internal components are accommodated in the housing 2. As a result, as shown in FIG. 10, the internal components are accommodated in the housing 2 in the order of the substrate 4, the heat generating component (for example, the SoC 41), the heat transfer member 5, the gasket 7, and the shielding member 6 from the front surface to the back surface in the direction perpendicular to the main surface of the substrate (Z-axis direction).

As shown in FIG. 10, when the second housing 22 is assembled with the first housing 21, the convex part 25 of the second housing 22 contacts the shielding member 6. At this time, the convex part 25 presses the heat transfer member 5 (and specifically, the metal plate 51) against the heat generating components on the substrate 4 via the shielding member 6. As a result, the degree of adhesion between the heat generating components, such as the SoC 41 and the Wi-Fi module 42, and the heat transfer member 5 can be enhanced, whereby the thermal conductivity from the heat generating component to the heat transfer member 5 can be increased. Thus, the convex part 25 can increase the thermal conductivity from the heat generating components to the heat transfer member 5 while forming an exhaust path from the fan 3 to the exhaust port 24, and can effectively improve the heat dissipation performance of the electronic device 1. That is, according to the present embodiment, an electronic device 1 having an improved heat dissipation design can be provided.

Furthermore, from another viewpoint, the convex part 25 presses the shielding member 6 against the heat transfer member 5 (and specifically, the metal plate 51). As a result, the gasket 7 provided between the heat transfer member 5 and the shielding member 6 is compressed, and the heat transfer member 5 comes into close contact with the shielding member 6. At this time, since the shielding member 6 is electrically connected to the ground electrode of the substrate 4, the heat transfer member 5 is electrically connected to the ground electrode of the substrate 4 via the shielding member 6. That is, the potential of the heat transfer member 5 can be set to the ground potential, whereby the electromagnetic shielding effect of the heat transfer member 5 can be improved. This is particularly effective when a part of the heat transfer member 5 (the heat dissipation fin 52 in the present embodiment) is exposed from the shielding member 6.

Furthermore, the shielding member 6 is attached to the substrate 4 in a state in which the engagement parts 62 thereof are elastically deformed. Thus, the engagement parts 62 receive a reaction force from the substrate 4, and there is a risk that the engagement between the engagement parts 62 and the side surface of the substrate 4 may be released due to this reaction force. In this regard, in the present embodiment, since the convex part 25 presses the shielding member 6 against the substrate 4, the engagement state between the engagement part 62 and the side surface of the substrate 4 is maintained. As a result, disengagement of the engagement between the engagement parts 62 and the side surface of the substrate 4 can be suppressed. Thus, the electrical connection between the shielding member 6 and the ground electrode of the substrate 4 can be stabilized, whereby a reduction in the electromagnetic shielding effect by the shielding member 6 and the heat transfer member 5 can be suppressed.

Though the preferred embodiments according to the present disclosure have been described above, the present disclosure is not limited to these embodiments, and various modifications and changes can be made within the scope of the claims. For example, the housing 2 may be formed from equal to or greater than three members (for example, a front member, a rear member, and a side surface member, etc.). Furthermore, in addition to the display, a power button, an operation button, a speaker hole, a USB port, etc., may be provided on the outer surface of the housing 2.

Furthermore, the shielding member 6 may be electrically connected to a ground electrode formed on the surface of the substrate 4 in addition to or in place of the ground electrode on the side surface of the substrate 4. Furthermore, the shielding member 6 may cover the heat dissipation fin 52 as long as a path for the air blown from the fan 3 to pass through the heat dissipation fin 52 and be exhausted from the exhaust port 24 can be secured. That is, the opening 61 may be omitted and the shielding member 6 may cover the entire heat transfer member 5.

Furthermore, the shielding member 6 may be omitted. In this case, the convex parts 25 of the housing 2 contact the heat transfer member 5 directly or via a gasket or the like, and press the heat transfer member 5 against the heat generating components on the substrate 4. If the shielding member 6 is omitted, it is preferable that the heat transfer member 5 be directly electrically connected to the ground electrode of the substrate 4 in order to enhance the electromagnetic shielding effect of the heat transfer member 5. For example, the metal plate 51 of the heat transfer member 5 is directly electrically connected to the ground electrode formed on the surface of the substrate 4. Note that even if the shielding member 6 is provided, the heat transfer member 5 may be directly electrically connected to the ground electrode of the substrate 4.

Furthermore, a heat dissipation plate, a heat dissipation sheet, a heat dissipation film, etc., may be arranged in the exhaust path as a heat transfer member in place of the heat dissipation fin 52. Further, the gasket 7 may be omitted, and the shielding member 6 pressed by the convex parts 25 may be in direct contact with the heat transfer member 5.

Furthermore, the first housing 21 and the second housing 22 may be composed of a metal material such as an aluminum alloy or a magnesium alloy, and may be formed by die casting, etc. In this case, since the thermal conductivity of metal is higher than that of resin, when the convex part 25 of the second housing 22 contacts the heat transfer member 5 directly or via the shielding member 6, the heat conducted from the heat generating components to the heat transfer member 5 can be released to the first housing 21 and the second housing 22, whereby the heat dissipation of the electronic device 1 can be further improved.

Furthermore, though the convex parts 25 are configured so as to press the heat transfer member 5 against the heat generating component while forming an exhaust path from the fan 3 to the exhaust port 24 in the embodiment described above, the convex parts may be configured so as to press the heat transfer member 5 against the heat generating components without forming an exhaust path. In this case also, the degree of adhesion between the heat generating components and the heat transfer member 5 can be increased, whereby an electronic device 1 having an improved heat dissipation design can be provided. Since the degree of adhesion between the heat generating component and the heat transfer member 5 can be increased when the housing 2 is formed by assembling the first housing 21 and the second housing 22, the heat dissipation performance of the electronic device 1 can be improved without generating additional operations in the production process.

Furthermore, the configuration of the convex parts formed in the housing 2 is not limited to a pair of convex parts 25 (two convex parts 25), and may be another number of convex parts (one or equal to or greater than three). Furthermore, the internal components may be attached to the inner surface 221 of the second housing 22 arranged on the rear side of the electronic device 1, and the first housing 21 arranged on the front side of the electronic device 1 may have the convex parts.

The manner of the installation of the shielding member is not limited to an embodiment in which the shielding member 6 covers the heat generating components and the heat transfer member 5. For example, a shielding wall or a shielding film may be provided as the shielding member on the heat generating components. That is, in the direction perpendicular to the main surface of the substrate (Z-axis direction), from the front to the back, the internal components may be accommodated by the housing in the order of the substrate, the heat generating component, the shielding member, and the heat transfer member, and the convex parts of the housing may be in contact with the heat transfer member.

Furthermore, the heat generating component provided in the electronic device 1 is not limited to an IC (integrated circuit) implemented on the substrate 4, such as the SoC 41 and the Wi-Fi module 42, and may be a battery accommodated in the housing 2, etc.

1. An electronic device, comprising:
a housing;
a fan accommodated in the housing;
a heat generating component accommodated in the housing; and
a heat transfer member which is in thermal contact with the heat generating component, wherein
the housing has an exhaust port, and a convex part protruding toward an interior space of the housing, and
the convex part presses the heat transfer member against the heat generating component and forms an exhaust path guiding air blown from the fan toward the exhaust port, and the heat transfer member is arranged in the exhaust path.

2. The electronic device according to claim 1, further comprising a substrate accommodated in the housing, wherein
the heat generating component is implemented on the substrate.

3. The electronic device according to claim 2, wherein
the heat transfer member is electrically connected to a ground electrode of the substrate.

4. The electronic device according to claim 2, wherein
the heat generating component includes a first heat generating component, and a second heat generating component having a heat generation amount which is less than the first heat generating component, and
in a plane view of the substrate, the first heat generating component is arranged in a position overlapping the exhaust path, and the second heat generating component is not arranged in a position overlapping the exhaust path.

5. The electronic device according to claim 2, further comprising a shielding member covering the heat generating component and the heat transfer member, wherein
the convex part presses the heat transfer member against the heat generating component via the shielding member.

6. The electronic device according to claim 5, wherein
the shielding member has an opening, and
the heat transfer member has a heat dissipation fin exposed from the opening and arranged in the exhaust path.

7. The electronic device according to claim 5, wherein
the shielding member is electrically connected to a ground electrode of the substrate, and
the convex part presses the shielding member against the heat transfer member, and the heat transfer member is electrically connected to the ground electrode via the shielding member.

8. The electronic device according to claim 5,
wherein the shielding member has an engagement part elastically deforming to engage with a side surface of the substrate, and the engagement part is electrically connected to a ground electrode of the substrate, and
the convex part presses the shielding member against the substrate so as to maintain an engagement state between the engagement part and the side surface of the substrate.

9. The electronic device according to claim 8, wherein
the engagement part has a protrusion holding the substrate in a thickness direction of the substrate.

10. The electronic device according to claim 8, wherein
the engagement part has a tapered tip extending outside the substrate.

11. A method for producing an electronic device, comprising:
forming a housing by assembling a first housing and a second housing such that a heat generating component and a heat transfer member which is in thermal contact with the heat generating component are accommodated in the housing, wherein
the first housing or the second housing has a convex part protruding toward an interior space of the housing, and the convex part presses the heat transfer member against the heat generating component when the first housing and the second housing are assembled.
